(19) United States
(12) Patent Application Publication
(10) Pub. No.: US 2025/0109498 A1
(43) Pub. Date: Apr. 3, 2025

(54) Hard X-ray Compatible Chamber for High Temperature In-Situ Material Processing

(71) Applicant: UCHICAGO ARGONNE, LLC, Chicago, IL (US)

(72) Inventors: Katherine J. Harmon, Mountain View, CA (US); Joseph Paul Heremans, JR., Chicago, IL (US); Matthew J. Highland, Chicago, IL (US); Angel Yanguas-Gil, Northbrook, IL (US); Stephan Hruszkewycz, Oak Park, IL (US)

(21) Appl. No.: 18/374,917

(22) Filed: Sep. 29, 2023

(51) Int. Cl. C23C 16/48; C23C 16/54; G01N 23/20008

(52) U.S. Cl. CPC C23C 16/483; C23C 16/54; G01N 23/20008

(57) ABSTRACT

Typical chemical vapor deposition (CVD) systems are unable to analyze a sample during CVD fabrication. A system and method for performing material deposition and in-situ analysis of a sample during CVD synthesis is described. The system includes a deposition chamber having an outer chamber wall surrounding a chamber volume and an inner sleeve disposed inside of the chamber volume with a buffer region between the outer chamber wall and the inner sleeve. A sample mount is disposed in the deposition volume to support a position and orientation of a sample in the deposition volume during CVD. Gas inlets and gas outlets are in fluid communication with the deposition chamber to respectively allow fluid to flow into, and out of, the deposition chamber. A thermal radiation source provides thermal radiation along a deposition axis to the sample disposed in the deposition volume.

### STATEMENT REGARDING FEDERALLY SPONSORED RESEARCH OR DEVELOPMENT

This invention was made with government support under Contract No. DE-AC02-06CH11357 awarded by the United States Department of Energy to UChicago Argonne, LLC, operator of Argonne National Laboratory. The government has certain rights in the invention.

### FIELD OF THE DISCLOSURE

The present disclosure relates to methods and systems for achieving high temperature heating in cold wall reactors under a size, visibility, and RF-constrained environment, and its application to perform chemical vapor deposition, and specifically, to perform X-ray imaging compatible chemical vapor deposition techniques.

### BACKGROUND

Fabrication via deposition of materials is employed in a wide range of industries including microelectronics, optoelectronics, coatings, sensors, medical, military, and security applications. The demand for high-quality devices with precise thickness, composition, and uniformity has driven the development of various deposition methods. Many of these processes require high temperatures, often exceeding 700° C. These may include physical vapor deposition processes such as evaporation or sputtering, and processes based on chemical reactions. In particular, Chemical Vapor Deposition (CVD) is one deposition technique that has emerged as a versatile and widely used technique capable of producing thin films, nanoscale devices, and microscale devices.

Conventional CVD techniques involve the chemical reaction of volatile precursor compounds in a gaseous phase to form solid thin films on a substrate's surface. These precursor compounds dissociate at elevated temperatures, releasing reactive species that undergo chemical reactions on the substrate's surface to build up the desired thin film. A key challenge of CVD is that the correlations between experimental conditions are very complex: process optimization is often done empirically and through long and costly growth-characterization cycles. Researchers and engineers have continuously explored innovations in CVD processes to enhance deposition efficiency, control, and film characteristics. This has led to the development of various modified CVD techniques, including plasma-enhanced CVD (PECVD), atomic layer deposition (ALD), and metal-organic CVD (MOCVD). Each of these techniques has advantages and drawbacks when working at certain dimensional scales as well as with fabricating with different types of materials.

One drawback of every CVD technology is the inability to evaluate the fabrication of a device, surface, or thin film during a fabrication cycle. Due to the harsh chemical, thermal, and pressure conditions of performing CVD, typical CVD chambers include materials that do not permit imaging of in-situ synthesis of materials. As such, a microscale, or molecular scale, understanding of fabrication processes and potential defects is not directly attainable using typical CVD systems. Any testing of such devices or surfaces must currently be performed ex-situ after fabrication has occurred. Therefore, an understanding of the fabrication process, and potential errors in fabrication, is not directly attainable and extensive trial and error over many fabrication cycles must be performed to achieve desired performance results. This trial and error fabrication approach results in very long development periods, wasted materials, and is expensive. Additionally, further insights into understanding rate-dependencies in deposited film quality during fabrication may be exploited to further enhance growth rates without sacrificing film quality. Due to these drawbacks, improved methods and systems for performing CVD, and specifically for performing analysis of CVD during fabrication, are desired.

### SUMMARY OF THE DISCLOSURE

In an embodiment, disclosed is a system for performing material deposition. The system includes a deposition chamber having (i) an outer chamber wall surrounding a chamber volume, (ii) an inner sleeve disposed inside of the chamber volume with a buffer region between the outer chamber wall and the inner sleeve, the inner sleeve surrounding a deposition volume for performing deposition of materials, (iii) a sample mount disposed in the deposition volume and configured to receive a sample to support a position and orientation of the sample in the deposition volume, and (iv) a vacuum port for generating a vacuum environment inside of the deposition chamber; one or more gas inlets in fluid communication with the deposition chamber to allow fluid, such as a gas phase, to flow into the deposition chamber; one or more heatsink elements thermally coupled to the deposition chamber configured to isolate heat within the deposition chamber near the sample mount; and a thermal radiation source configured to provide thermal radiation to the deposition volume along a deposition axis, the deposition axis being perpendicular to a normal vector of the outer chamber wall and the sample mount being disposed along the deposition axis.

In variations of the current embodiment, the radiation source comprises a laser optically coupled to the deposition volume to provide radiation to the deposition volume. The laser may comprise an infrared laser. In continued variations, the one or more gas fluid inlets includes a first gas fluid inlet in fluid communication with a first precursor zone; a second gas fluid inlet in fluid communication with a second precursor zone, and a third gas fluid inlet in fluid communication with a third precursor zone.

A method of actively imaging a sample during fabrication of the sample, the method including: providing a sample to a sample mount disposed in a deposition chamber, the deposition chamber having: an outer chamber wall surrounding a chamber volume, and an inner sleeve disposed inside of the chamber volume with a buffer region between the outer chamber wall and the inner sleeve, the inner sleeve surrounding a deposition volume; generating a vacuum inside of the deposition chamber; providing, via one or more fluid inlet ports, reactive precursor agents to the deposition volume; providing, via a thermal radiation source, thermal radiation to the sample, the thermal radiation provided along a deposition axis, and wherein the sample mount is disposed along the deposition axis; providing, via an X-ray radiation source, X-ray radiation to the sample; and detecting, via an X-ray detector, the scattered X-ray radiation.

### BRIEF DESCRIPTION OF THE DRAWINGS

FIG. 1 is a perspective view diagram of a hard X-ray compatible chemical vapor deposition (CVD) system for in-situ synthesis characterization.

FIG. 2 is a side-view diagram of an internal cross-section of a hard X-ray compatible CVD system for in-situ synthesis characterization.

FIG. 3 is a cross-sectional perspective view of a reactor region of the CVD system of FIGS. 1 and 2.

FIG. 4A is a zoomed in cross-sectional side-view of an upper portion of the reactor region of FIG. 3.

FIG. 4B is a perspective view of the outer surface of a CVD showerhead with a first gas inlet, second gas inlet, and third gas inlet.

FIG. 5A is a zoomed in cross-sectional side-view of a central deposition chamber of the CVD system of FIGS. 1 and 2.

FIG. 5B is a perspective cross-sectional view of the sample mount of FIG. 5A.

FIG. 5C is a perspective view of the sample mount of FIG. 5A.

FIG. 6A is a cross-sectional perspective view of a lower portion of the reactor region and the base region of the system of FIGS. 1 and 2.

FIG. 6B is another cross-sectional perspective of the reactor region and the base region showing an entire sample mount and hollow mount tube.

FIG. 7 is a perspective view of a base region, outer chamber wall, and chamber annulus of the reactor region of the system of FIGS. 1 and 2.

FIG. 8 is an image of a 5 mm square sample disposed on a top surface of a sample mount for performing CVD synthesis.

FIG. 9 is an image of a 10 mm square sample disposed on a top surface of a sample mount for performing CVD synthesis.

FIG. 10 is a heat map of a sample generated by an optical pyrometer during CVD synthesis including the laser power used with peak temperature near the center of the sample.

FIG. 11A is an atomic force microscope (AFM) image of a SiC substrate before growth showing approximately 3 angstrom high terraces.

FIG. 11B is a plot of substrate height in angstroms of a line cut of the 6H-SiC substrate of FIG. 11A.

FIG. 11C is a diagram of an atomic crystal structure diagram of the 6H-SiC substrate of FIG. 11A.

FIG. 12 is an X-ray Crystal Truncation Rod (CTR) measurement plot of the substrate of FIG. 11A before growth for CVD deposition, and after an hour of deposition under 1400° C. with a flow of 5% H₂/Ar.

FIG. 13 is a plot of a time-resolved measurement of changes in X-ray scattering intensity at a specific surface-sensitive momentum transfer along a CTR during gas flow conditions of 5% H₂/Ar and reactive SiC precursor flow conditions.

FIG. 14 is another plot of time-resolved measurement of changes in X-ray scattering intensity at a specific surface-sensitive momentum transfer along a CTR during gas flow conditions of 5% H₂/Ar and different reactive SiC precursor flow conditions than presented in the data of FIG. 13.

FIG. 15 is a plot of an X-ray CTR measurement showing Bragg peaks of a substrate before CVD deposition and after an hour for deposition under 1400° C. with a flow of 5% H₂/Ar.

FIG. 16 is a plot presenting the post-CVD synthesis X-ray CTR measurement of FIG. 15 with fringes indicating the presence of a deposited film.

FIG. 17 is a plot of an X-ray CTR measurement showing Bragg peaks of a 0.2 degree miscut 4H-SiC substrate with separate miscut rods before CVD deposition.

FIG. 18 is a plot of X-ray CTR data for a CVD fabricated thin film on the sample of FIG. 17 after various CVD growth cycles, which resulted in a mixed polytype heterostructure of 3C-SiC on the 4H-SiC substrate, as indicated by addition Bragg peaks at reciprocal lattice indices of 1.33 and 2.67.

FIG. 19 is a flow diagram of a method of performing in-situ X-ray analysis of a sample during CVD synthesis using example systems described herein.

### DETAILED DESCRIPTION

A molecular scale understanding of materials synthesis is essential for optimizing material functional properties. Understanding deposition molecular thickness, gaps or voids, compositions, etc., is essential for designing effective devices having specific chemical, electrical, mechanical, magnetic, and quantum properties. As such, it is desirable to observe and analyze material film structure during synthesis. The disclosed chemical vapor deposition (CVD) system enables in-situ imaging and observation of device fabrication during CVD synthesis.

Silicon carbide (SiC) has emerged as a promising wide bandgap semiconductor material for applications including medical devices, nano and micromaterials, security applications, quantum devices, etc. SiC exhibits multiple, optically-active point defect complexes with characteristic photoluminescence wavelengths that span the visible to infrared regimes. This broad optically active region is due to the fact that SiC material growth has over 200 polytypes, or subtle variations in lattice structure, that lead to different electronic properties of the distinct polytypes. The ability to selectively grow a uniform, specific SiC polytype and, further, to precisely tune material electronic properties is challenging due to close formation energies of the polytypes. Due to limitations of traditional CVD fabrication systems and methods, attempts to study and understand SiC growth have largely relied on post-growth (i.e., ex-situ) characterization tools from which growth mechanisms can only be inferred and which are incompatible with high temperatures needed for SiC synthesis (˜1000-2000° C.). While some advancements have been made, the levels of defects in fabricated devices characterized using ex-situ analysis methods impedes optimal device performance and requires additional time and resources to tune a system to fabricate a component or device with desired electrical properties. Structural defects alter emission wavelengths of optically active “color centers,” complicating the use if SiC devices for quantum information science (QIS) applications. If analyzed and understood in-situ during CVD fabrication, a molecular scale understanding of the processes could result in further observations of useful emergent quantum phenomena, suggesting a broad range of technological tunability across a variety of applications. As described, the proposed CVD system can be implemented in further understanding SiC polytypic heterostructures, which are common due to similar polytype formation energies and are typically considered undesirable. This could lead to new capabilities for the coherent control of SiC quantum defects as well as for nanofabrication and other device technologies.

Achieving reproducible, high quality SiC polytypic heterostructures requires a detailed understanding of the surface energetics and structural modifications during SiC growth that drive polytype stability. Current technologies are unable to observe or provide any insight into the required surface and molecular features to determine the formation of surface structures and associated energies during fabrication. The disclosed CVD system provides a hard X-ray compatible in-situ chamber allowing both infrared and X-ray analysis of CVD synthesis during fabrication. Hard X-rays with photon energies greater than 20 keV can penetrate the thick chamber walls of the CVD chamber to directly probe the SiC surface structure. Meanwhile, crystal truncation rod (CTR) scattering is a highly surface-sensitive probe that can distinguish between different SiC polytypes as well as probe the terminal layer of the SiC stacking sequence. The system allows for the observation and analysis of the fabrication of the various SiC polytypes and further allows for the engineering and tuning of the CVD chamber parameters for fabricating desired polytypes, layer thicknesses, material densities, etc. While described in reference to fabrication of SiC polytypes, a person of ordinary skill in the art would understand that the described CVD system may be used to fabricate any suitable materials. Refractory materials, for example, may be fabricated using the described system. Refractory materials require temperatures above 1200° C. for which existing in-situ synthesis chambers (e.g., molecular beam epitaxy) are unsuitable. Additionally, refractory materials must be stable in extreme environments and the described system can provide a means for processing and analyzing these materials due to the capability of the chamber to reach such high temperatures. Thus, material stability, failure modes, and other material processes and changes can be directly analyzed and characterized in-situ using the disclosed system.

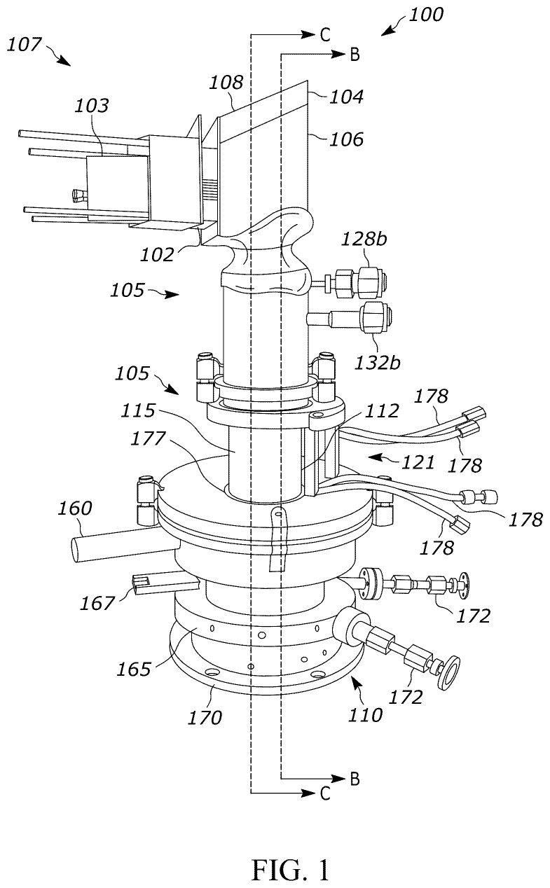

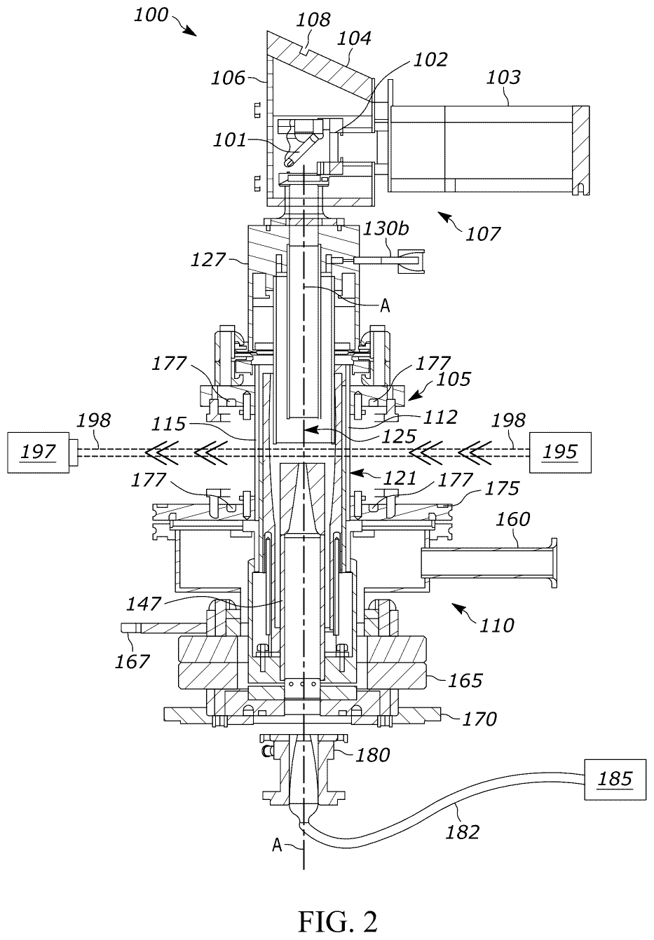

FIG. 1 is a perspective view diagram of a hard X-ray compatible CVD system 100 for in-situ synthesis characterization. FIG. 2 is a cross-sectional side-view diagram of the system 100 taken along section B-B of FIG. 1. While often described in reference to performing deposition, it should be understood that the system 100 may further be used for performing material or surface etching and annealing of a surface while additionally performing in-situ measurements of the surface or material. The system 100 includes a reactor region 105, an imaging region 107, and a base region 110. Each of the reactor region 105, the imaging region 107, and the base region 110 are disposed adjacent to each other along a central axis A. The central axis A, may further be referred to herein as the deposition axis. During operation, CVD deposition occurs on a sample disposed along the deposition axis A. As illustrated in FIGS. 1 and 2, the reactor region 105 is disposed below the imaging region 107 and above the base region 110, with the reactor region 105 being between the imaging region 107 and the base region 110. The imaging region 107 includes elements and devices that perform optical imaging of a sample during CVD synthesis, the reactor region 105 includes elements and devices for providing chemical precursors to a sample to perform CVD synthesis, and the base region 110 includes elements and devices for (i) manipulating the sample orientation inside of the system 100, (ii) mounting the sample in a beam line for X-ray imaging, and (iii) providing thermal radiation to a sample disposed in the reactor region.

In addition to the elements of the reactor region 105, imaging region 107, and base region 110, the system 100 additionally includes a thermal radiation source 185 that provides thermal radiation to the radiation chamber via an optical fiber 182. The optical fiber 182 is coupled to the base region 110 via an optical fiber coupler 180, discussed in more detail further herein. The thermal radiation source 185 may be a laser radiation source configured to provide infrared (IR) radiation to the reactor region 105, and specifically to provide the IR radiation along the central axis A to a sample disposed in the reactor region 105. The thermal radiation source 185 may provide up to 1 kW of power, or more depending on a required, or desired, heat energy to provide to a sample. In examples, the thermal radiation source 185 may include one or more lasers, such as an infrared laser, or another type of laser with output powers of 500 W, 750 W, 1 KW, 500 W or greater, 1 KW or greater, or 1.5 KW or greater.

Typical CVD systems provide heat to a sample via a resistive heater thermally coupled to a sample mount or positioned near a sample. Additionally, resistive heat sources provide thermal energy to other elements of the CVD system such as a sample mount or nearby walls and structures. As such, the heat from the resistive heat source can affect the surrounding elements and structures causing complications or further stringent material requirements of the CVD system. The positions of resistive coils and elements would further obstruct an X-ray beam path reducing the ability to probe reciprocal space for analyzing the molecular structure of a sample during deposition or etching. Providing the thermal radiation to the bottom of the sample along the central axis A further prevents the thermal radiation source 185 from being in the path of any other imaging devices or elements of the system 100.

Other CVD systems may use hot-wall SiC CVD reactors for performing CVD. These types of systems are not compatible with performing in-situ X-ray measurements, such as via synchrotron provided radiation. These types of systems are extremely large and have big enclosures to prevent users from burning themselves on the hot outer chamber walls of the system. Additionally, due to the large sizes and fixed components of the hot-wall systems, these types of setups are unable to be moved into and out of an X-ray beam line or onto or off of a diffractometer. Also, the system would not allow for rotation ofa sample inside of the chamber to perform enough measurements to characterize the material growth at the molecular scale. The described system is a cold-walled system that prevents heat from reaching the outer walls and surfaces of the CVD chamber. The cold-walled system described is smaller in form factor allowing for it to be moved and reconfigured into and out of beam-lines without transferring any heat to beamline components.

The system 100 further includes an X-ray radiation source 195 configured to provide an incident X-ray beam 198 to a sample disposed in the reactor region 105, discussed further herein. The X-ray radiation source 195 may be a synchrotron radiation source, an undulator, a wiggler, and/or a bending magnet. The incident X-ray beam 198 then is used to probe the sample through various means (e.g., X-ray diffraction, X-ray spectroscopy, etc.) and an X-ray detector 197 then detects the X-ray beam 198. Various X-ray probe based analytics are then performed to determine various material, molecular, and atomic properties and characteristics of the sample during CVD fabrication in the reactor region 105.

The imaging region 107 includes an optical enclosure 106 that houses a dichroic mirror 101, a beam stop 104, and a shortpass filter 102. The dichroic mirror 101 transmits excess radiation from the thermal radiation source (i.e., laser radiation), propagating along the central axis A that was not absorbed by the sample during CVD synthesis. The excess radiation from the thermal radiation source is then absorbed by the beamstop 104 to collect the thermal radiation. The dichroic mirror 101 reflects other wavelengths of black body radiation that are emitted from a sample that is heated in the reaction region 105 during CVD fabrication. In examples, the dichroic mirror may transmit IR radiation. In such an example the dichroic mirror may be a longpass mirror with a cutoff wavelength of 650 nm, of between 650 and 700 nm, of 750 nm, of between 700 and 900 nm, of 950 nm, or of between 600 and 1000 nm. The dichroic mirror 101 reflects the black body radiation through the shortpass filter 102. The shortpass filter 102 has a cutoff wavelength of 1000 nm, 900 nm, 800 nm, 700 nm, or between 600 and 1000 nm. In examples, the shortpass filter 102 further filters any additional excess radiation from the thermal radiation source and passes black body radiation emitted from the sample during CVD synthesis.

An optical pyrometer 103 detects the black body radiation that is transmitted through the shortpass filter 102. An optical pyrometer 103 can detect black body radiation across temperatures ranging from about 700° C. to about 4000° C. by comparing the brightness of a heated object, such as a sample during CVD synthesis, to known values and heat sources. The optical pyrometer 103 collects the black body radiation and provides a two-dimensional (2D) thermal map of a sample during the CVD synthesis. The imaging region 107 further includes a thermocouple 108 embedded in the optical enclosure 106 to measure the temperature and heat emitted by the beamstop 104 to ensure that the beamstop 104 remains below a certain temperature as exceeding this temperature would indicate an unplanned or unexpected increase in laser power from the thermal radiation source passing through the deposition region, which would indicate fracture and destruction of a sample. Thus, a temperature in excess of a cutoff temperature triggers a cessation of the deposition process so that the sample can be replaced.

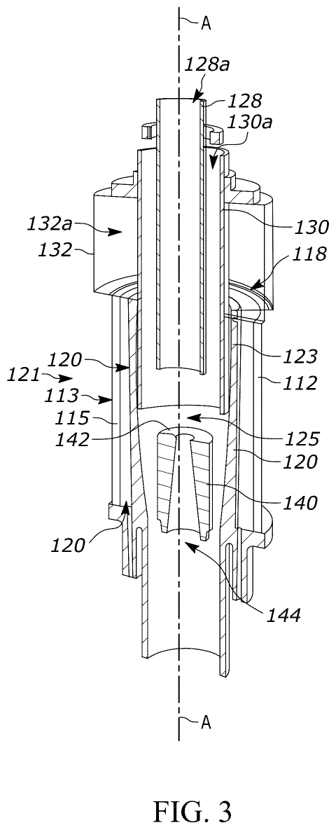

FIG. 3 is a cross-sectional perspective view of the reactor region 105 of the CVD system 100 taken along section A-A of FIG. 1. The reactor region 105 includes a deposition chamber 121 having an outer chamber wall 115 that surrounds a chamber volume 118 along the central axis A. The outer chamber wall 115 may be a cylindrical structure disposed concentrically around the central axis A. The inside of the chamber volume 118 is vacuum-controlled to precisely control the pressures of various materials in the deposition chamber 121 for performing CVD synthesis. The outer chamber wall 115 is a material that is transmissive to X-ray radiation, and is opaque to the radiation wavelength provided by the thermal radiation source for safety, to allow for probing of a component being synthesized inside of the deposition chamber 121 during CVD synthesis. For example, the outer chamber wall 115 may be fused quartz, a material that is non-reactive to halides, or a material not containing oxides.

An inner sleeve 123 is disposed inside of the chamber volume 113 with the inner sleeve 123 surrounding a deposition volume 125 around the central axis A. The inner sleeve 123 is surrounded by the outer chamber wall 115, and the inner sleeve 123 is inset from the outer chamber wall 115. The distance between the inner sleeve 123 and the outer chamber wall 115 forms a buffer region 120 between the inner sleeve 123 and the outer chamber wall 115. The inner sleeve 123 may be a graphite material, or SiC coated graphite. The buffer region 120 is under vacuum in order to isolate fused quartz of the outer chamber wall 115 from contacting any precursor gasses. In any examples, the inner sleeve 123 is a thermally insulating material. In examples, the inner sleeve 123 is a material that is transmissive to X-rays to allow for X-ray probing of a substrate or device being fabricated in the deposition volume 125 during CVD synthesis. The inner sleeve 123 provides a barrier between the deposition volume 125 and the buffer region 120 such that the pressures and chemical composition inside of each of the deposition volume 125 and the buffer region 120 may be different, or independently controlled.

The buffer region 120 has a narrow opening at the bottom with channels providing fluid connection of the buffer region 120 to a vacuum pull 160. The deposition volume 125 is also in fluid communication with the vacuum pull 160 to generate a vacuum in the deposition volume 125 and to allow for precursors to flow out of the deposition volume 125 via the vacuum pull 160. Since both the buffer region 120 and the deposition volume 125 are being pulled under vacuum via the vacuum pull 160, there is unidirectional air flow away from both the buffer region 120 and the deposition volume 125. Due to the unidirectional flow, the precursor gasses do not flow against the unidirectional vacuum pull into the buffer region 120 preventing any precursors from interacting with the outer chamber wall 115. The vacuum pull 115 acts as a gas outlet or fluid outlet port for the system 100 to remove gasses, such as excess precursors or air, from the system 100 to generate a vacuum.

The inner sleeve 123, being a thermal insulator, acts as a temperature barrier between the deposition volume 125, and the buffer region 120 and outer chamber wall 115. The inner sleeve 123, and reduced or lack of flow through the buffer region 120, further allows for a much higher vacuum (i.e., lower pressure) in the buffer region 120 than the vacuum in the deposition volume 125. The inner sleeve 123 and the lower vacuum buffer region 120 assist with heat isolation to isolate heat within the deposition chamber. The inner sleeve 123 further isolates chemical precursors in the deposition volume 125 and prevents the chemical precursors from contacting other materials which may react to the chemical precursors. For example, in implementations with graphite out chamber walls 115, some chemical precursors could cause combustion, or form undesired compounds such as bleach like compounds, if the precursors reach the oxygen containing fused quartz. Additionally, the buffer region further prevents the outer chamber walls 115 from reaching temperatures that may result in undesired formation of compounds such as bleach types of compounds via aggressive halide chemistry processes. Together with other thermal control features, such as elements of the sample mount further discussed herein, the buffer region 120 assists in reducing heat to elements of the system and prevents distortion or damage to components such as O-rings.

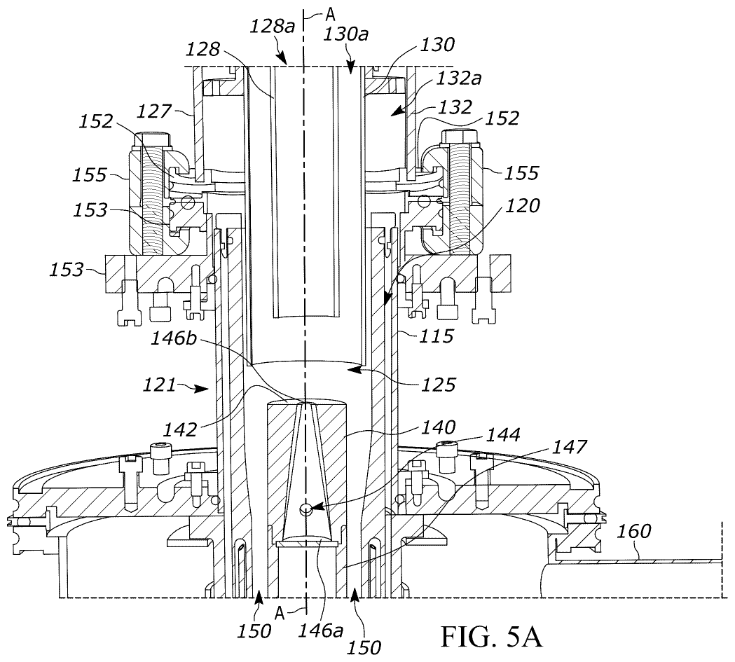

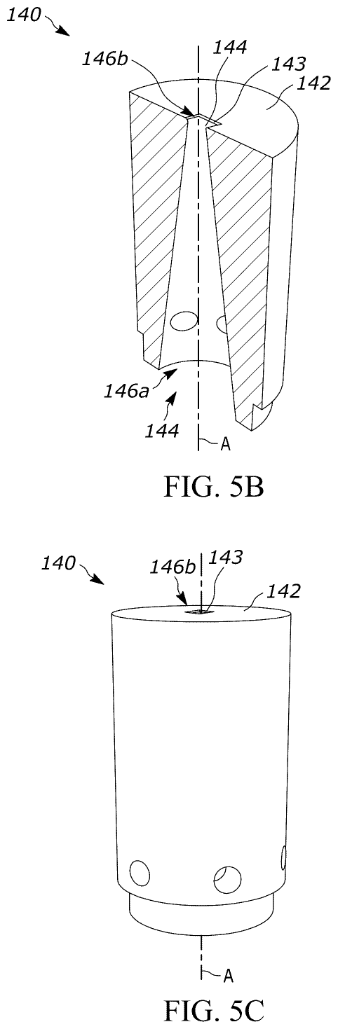

A sample mount 140 is disposed inside of the deposition chamber 121 along the central axis A. The sample mount 140 is physically coupled to a hollow mount tube 147, illustrated in FIGS. 2 and 5, to maintain a position of the sample mount 140 along the central axis A. The sample mount 140 has a top surface 142 and a central bore 144 that passes through the entire length of the sample mount 140 along the central axis A. The central bore 144 has a radius such that heat radiation, such as laser radiation, may pass through the central bore 144 of the sample mount 140 to reach a sample mounted on the top surface 142 of the sample mount 140. As illustrated, in FIGS. 3, 5A, 5B, and 6A the central bore 144 may have a tapered radius with a wider radius away from the top surface 142, and gradually tapering down to a narrower radius at the top surface 142. The tapered radius leads to a distributed area over which the excess laser radiation from a large thermal radiation beam spot size is incident. Thereby, the tapered radius of the central bore 144 reduces the power per unit area of incident radiation on the wall of the central bore 144 and mitigates the formation of thermal hot spots on the sample mount.

The tapering of the radius of the central bore 144 further provides additional thermal isolation of the heat at or near a sample disposed on the top surface 142. The tapered radius limits the contact points between the sample mount 140 and a steel hollow mount tube 147 to which the sample mount 140 is physically coupled. The reduced points of contact between the sample mount 140 and the hollow mount tube 147 slows the thermal conduction from the graphite sample mount 140 to surrounding elements of the deposition chamber 121. Without the tapered radius, there would be more thermal conduction of heat from the sample to the surrounding components, and heat may possibly even flow to beamline components in thermal contact with the chamber, 121 all of which have their own time constants for thermal equilibration. Anything in thermal contact that takes time to thermally equilibrate can affect the sample height in the X-ray beam. The sample height must remain stable to properly perform X-ray measurements and characterization of the sample during deposition or etching of the sample. In the disclosed system, the sample height may oscillate slowly over a period of hours which is sufficient to carry out X-ray measurements during operation. Therefore, the tapered radius of the central bore 144 allows for more isolation of heat to the top surface and region around the sample which allows for more stable sample height enabling the in-situ X-ray measurement of a sample during fabrication.

The sample mount 140 may include graphite, SiC coated graphite, and tungsten. The sample mount 140 may be modular so that it is removable and replaceable to mount different samples or to provide different thermal radiation beam profiles to the sample for performing CVD synthesis. For example, a given sample mount 140 may have a central bore 144 with a wider radius to allow for a larger or wider thermal radiation beam to propagate through the central bore 144, or the sample mount 140 may have a top surface 142 with more area to mount a larger sample for CVD synthesis. During CVD synthesis, a sample substrate is mounted onto the top surface 142 of the sample mount 140. CVD is then performed by building layers onto the sample substrate by providing a desired mixture of precursors and simultaneously providing heat to the sample substrate via the thermal radiation source 185. While described as a sample substrate, the sample may additionally include epitaxial graphene, a nanofabricated surface, channels in a surface, tapered channels or ridges, or another type of surface or surface structure. Additionally, the sample may have a sputtered back-side coating (e.g., on a surface toward the central bore 144 of the sample more 140), for example with tungsten, to improve the absorption and thermal coupling of the thermal radiation to the sample. While described herein in multiple examples as fabricating SiC, the sample may be used for deposition of p-type materials, n-type materials, insulator materials, materials with quantum defects, various material polytypes, heterojunction interfaces between various materials, semiconductor materials, CMOS device structures, structures, and surfaces for quantum devices, etc.

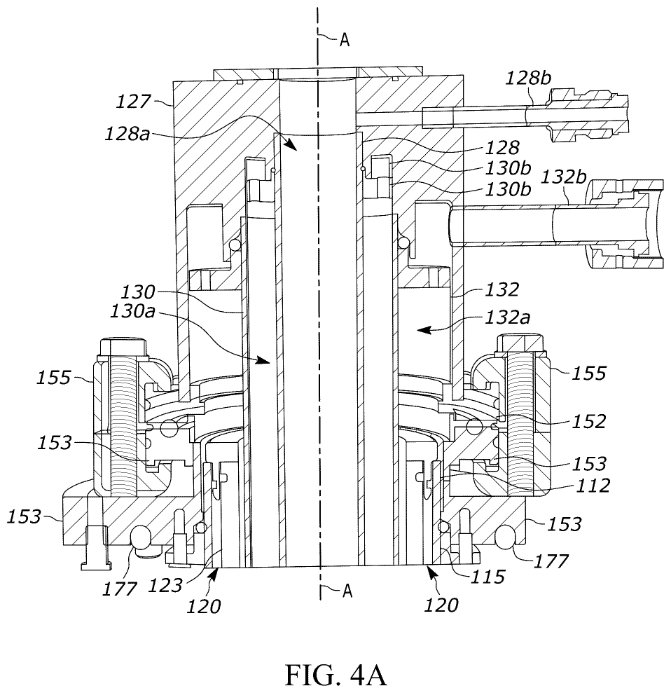

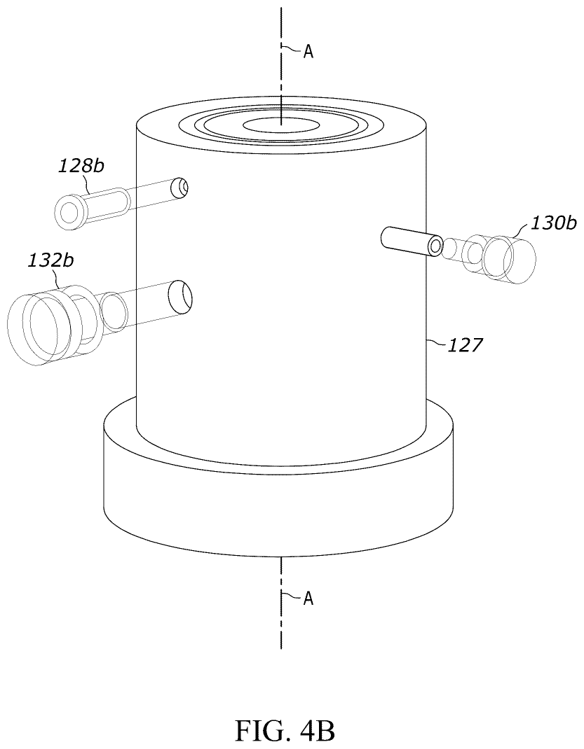

FIG. 4A is a zoomed in cross-sectional side-view of an upper portion of the reactor region 105 taken along section B-B of FIG. 1, and FIG. 5 is a zoomed in cross-sectional side-view of the central deposition chamber 125 taken along section B-B of FIG. 1. For completeness and clarity, FIGS. 4A and 5 will be described simultaneously. As illustrated in FIG. 4A the reactor region further includes (i) a first precursor chamber 128 disposed along the central axis A, with the first precursor chamber 128 surrounding a first precursor zone 128a, (ii) a second precursor chamber 130 disposed concentrically around the first precursor chamber 128 forming a second precursor zone 130a between the first precursor chamber 128 and the second precursor chamber 130, and (iii) a third precursor chamber 132 disposed concentrically around the first and second precursor chambers 128 and 130 forming a third precursor zone 132a between the third precursor chamber 132 and the second precursor chamber 130. Each of the first, second, and third precursor zones 128a, 130a, and 132a are respectively in fluid communication with a first, second, and third gas inlet 128b, 130b, and 132b. Each of the first, second and third gas inlets 128b, 130b, and 132b, provides each respective precursor zone with chemical precursors for performing CVD synthesis in the deposition region 125. The three different and independent precursor zones 128a, 130a, and 132a, and three independent gas inlets 128b, 130b, and 132b, allow for the independent and precise control of the amount of precursors, and the amount of mixing of the precursors, before the precursors reach the deposition chamber 125 for CVD synthesis. To better withstand the required heat for performing CVD, the first, second, and third precursor chambers may each independently be graphite, a material not containing oxygen, or another material capable of withstanding the requisite high temperatures and compatible with chemical precursors. In examples, the first and second precursor zones 128a and 130a may be used to introduce precursors into the deposition chamber 121, while the third precursor zone 132a may additionally introduce a precursor, or may otherwise provide a non-precursor gas flow. Introducing a non-precursor gas flow in the third precursor zone 132a assists in preventing the precursors from contacting, and causing potential degradation of, the inner sleeve 123.

The three independent gas inlets 128b, 130b, and 132b are physically connected to, and provide fluid flow through, a showerhead 127. FIG. 4B is a perspective view of the outer surface of the showerhead 127 with the first gas inlet 128b, second gas inlet 130b, and third gas inlet 132b. The first and third gas inlets 128b and 132b are illustrated as being orthogonally arranged on the showerhead 127 relative to the second gas inlet 130b around the central axis A. Other geometric arrangements of the three gas inlets 128b, 130b, and 132b are envisioned. For example, all three gas inlets 128b, 130b, and 132b may be on a same side of the showerhead 127, or the three gas inlets 128b, 130b, and 132b may all be 90 degrees apart from each other around the perimeter of the showerhead 127. The three gas inlets 128b, 130b, and 132b may be arranged anywhere around the showerhead 127 with each gas inlet 128b, 130b, and 132b independently coupled to the respective first, second, and third precursor zones 128a, 130a, and 132a. FIG. 5A also shows an exhaust channel 150 that surrounds both the sample mount 140 and hollow mount tube 147. The exhaust channel 150 allows for excess chemical precursor to flow out of the deposition chamber 125. The exhaust channel 150 is in fluid communication with the vacuum pull 160 to expel excess chemical precursors, and additional chemicals formed from the CVD synthesis, from the deposition chamber 125.

FIG. 5B is a perspective cross-sectional view of the sample mount 140 taken along section B-B, and FIG. 5C is a perspective view of the sample mount 140. As shown in FIGS. 5A and 5B, the central bore 144 of the sample mount 140 extends the entire length of the sample mount 140 along the central axis A. The central bore 144 forms an aperture at each end of the sample mount 140 along the central axis A. A lower aperture 146a allows thermal radiation to enter the bore, and an upper aperture 146b, at the top surface 142 of the sample mount 140, allows the thermal radiation to heat a sample mounted to the top surface 142 of the sample mount 140. The top surface 42 additionally has a retracted mounting ledge 143 on which a sample may be disposed. The retracted mounting ledge 143 is the only surface into which the sample may come into physical contact with the sample mount 140. Due to the reduced amount of physical contact between the sample and the sample mount 140, there is low thermal coupling or conductivity between the sample and the sample mount 140 which further isolates heat in the sample from transferring to the sample mount 140 and other nearby components. The retracted mounting ledge 143 further supports the position of a sample along the central axis A but acting as a frame for the sample to maintain a lateral position of the sample relative to the central axis A. The high thermal isolation of the heat to the sample causes a high thermal gradient slope across a sample during etching or deposition. This high thermal gradient can cause degradation of a sample or further cause the sample to shatter due to high thermal stress across the sample. This is prevented or mitigated by expanding the beam spot size of the thermal radiation on the sample via a collimator to couple the laser fiber optic 182 to the sample chamber, or by a series of lenses, or a combination thereof. The thermal map of the sample is monitored to ensure the sample does not undergo any failures due to the high thermal gradient.

Illustrated in FIG. 5A, the showerhead 127 includes a showerhead annulus 152 that is used to physically couple the showerhead 127 to the outer chamber wall 115. The annulus further provides a vacuum seal with the outer chamber wall 115 to form a vacuum inside of the deposition volume 125 and the rest of the reactor region 105. A series of chamber annuli 153 are physically coupled to the outer chamber wall 115 via a series of screws and clamps, illustrated in FIG. 5, and a vacuum clamp 155 physically couples the showerhead annulus 152 with one of the chamber annuli 153 to form the vacuum between the showerhead 127 and the deposition volume 125. While illustrated as using clamps, screws, and pins, various components of the system 100 may be physically coupled via other means. Additional elements such as O-rings, sealant gels and pastes, as well as other vacuum assistive measures may also be used to bond parts and form a vacuum between elements of the system 100. The chamber annuli 153 further include one or more heat sink grooves 177. The heat sink grooves 177 are configured to hold cooling lines 178 to flow cooling fluid, such as chilled water, through the cooling lines 178. The cooling lines 178 act as heat sink elements that help isolate the heat to the sample and region around the sample, including the sample mount 140 and specifically toward the top surface 142 of the sample mount 140. The heat sink elements further prevent significant heat from reaching other elements of the system 100, such as O-rings and seals, which prevents the seals and O-rings from degradation due to the thermal energy. The fluid cooling lines 178 provide on the order of 500 W of heatsink capacity. In examples, the heat sink elements may provide up to 500 W, 750 W, 1000 W or more heatsink capacity.

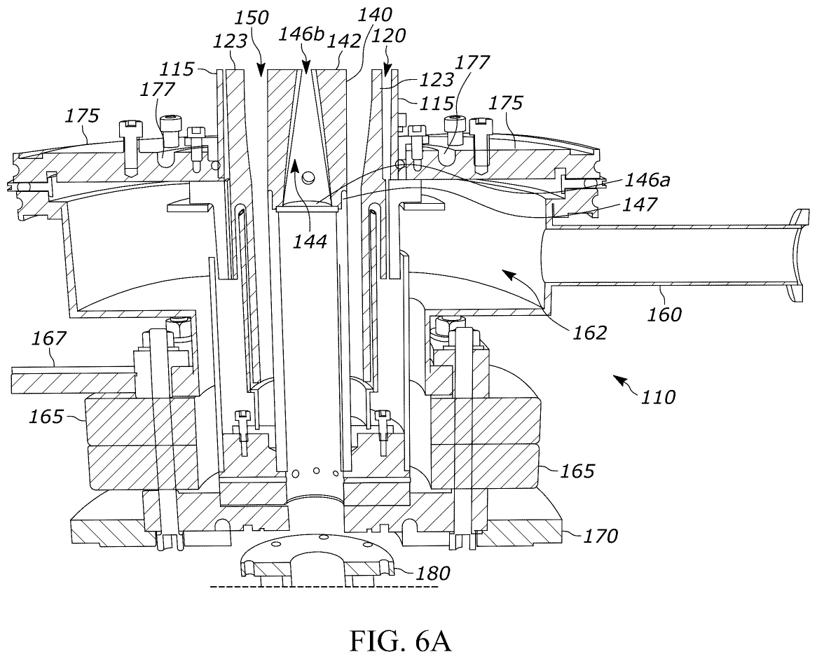

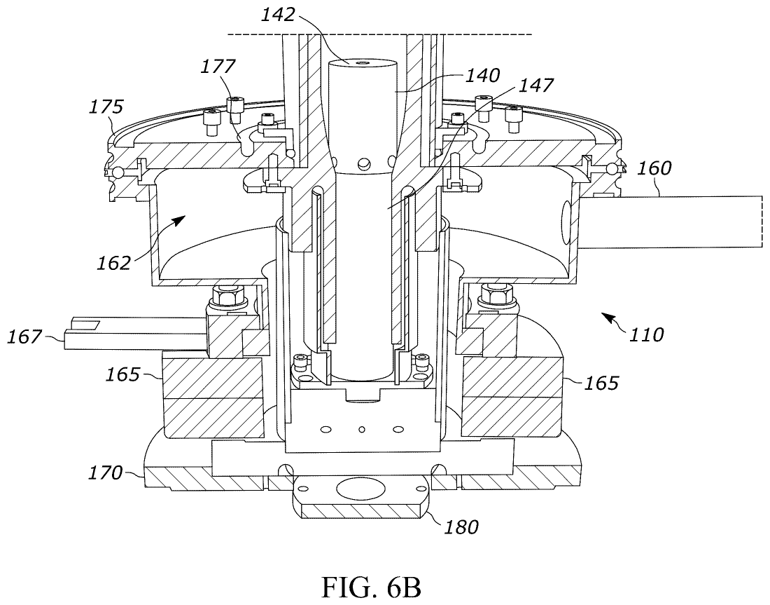

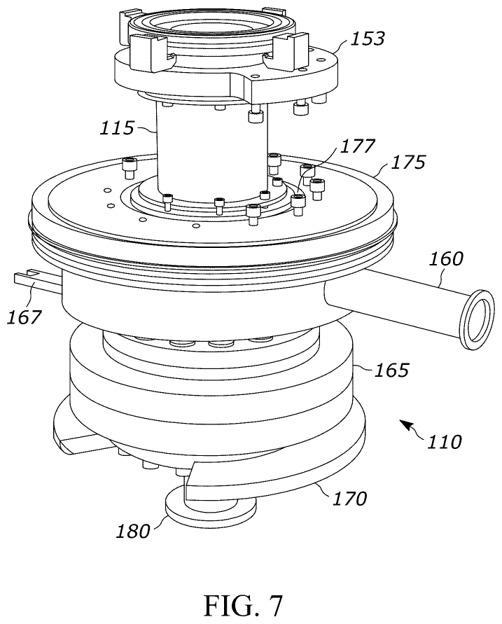

FIG. 6A is a cross-sectional perspective view of a lower portion of the reactor region 105, and the base region 110, of the system 100. FIG. 6B shows a different cross-sectional perspective, along section C-C of FIG. 1 of the reactor region 105 and the base region 110 with the cross-section being at a different plane than that of FIG. 6A. FIG. 6B shows the entire sample mount 140 and hollow mount tube 147. FIG. 7 is a perspective view of the base region 110, and the outer chamber wall 115 and chamber annulus 153 of the reactor region 105. For completeness, the base region 107 will be described with continued reference to each of FIGS. 6A, 6B, and 7. A base annulus 175 and associated screws and clamps physically couple the base region 100 to the reactor region 105 to form a vacuum between the base region 110 and the reactor region 105. The base annulus 175 includes one or more heat sink grooves 177 to provide cooling lines 178 therethrough. The cooling lines 178 may flow chilled water, or another fluid, through the cooling lines 177 to provide a heat sink to the reactor region 105.

The exhaust channel 150 empties into an exhaust chamber 162, which is in fluid communication with the vacuum pull 160 to allow excess chemical precursors, and resultant chemicals from the CVD synthesis, to flow out of the system 100. While illustrated as a single vacuum pull 160, the system 100 may include more than one output vacuum pull 160 to allow gases, fluids, and chemicals to flow out of the deposition region 125. Each of the exhaust channel 150 and vacuum pull 160 act generally as gas outlets in fluid communication with the deposition chamber 121 to allow fluid to flow out of the deposition chamber 121. The base region 110 further includes a rotary stage 165 that is physically coupled to the hollow mount tube 147. The rotary stage 165 enables the rotation of the hollow mount tube 147 and the sample mount 140 without the need to rotate the entire reactor region 105 or any other elements of the system 100. The ability to rotate the sample mount 140 allows for X-ray probing and imaging of different regions of reciprocal space for a sample mounted onto the sample mount 140 during CVD synthesis. The coupling of the rotary stage 165 to the hollow mount tube 147 simplifies the control of the orientation of the sample mount 140 by removing the need to rotate other elements such as any electrical or fluid lines, any X-ray or radiation sources, any imaging devices, etc. The use of the rotary stage 165 reduces the complexity of the system and allows for more robust analysis of samples during CVD synthesis.

A mounting fork 167 and diffractometer mount 170 physically position the deposition chamber 121 in the X-ray beam 195. The mounting fork 167 stabilizes the elements of the reactor region 105 in a position along an X-ray beam for performing in-situ measurements during CVD or etching. The mounting fork 167 also prevents movement of the system 100, such as tilting of the deposition chamber 121 or other elements of the system, during rotation of the sample mount 140. The mounting fork 167 maintains the orientation of the upper half of the chamber while allowing the sample mount 140, and any sample disposed thereon, to rotate. The mounting fork 167 assists in decoupling the orientation of the sample mount 140, and any sample thereon, from the orientation and position of other elements of the system 100 (e.g., the outer chamber wall 115, the inner sleeve 123, elements of the upper portion of the reactor region of FIG. 4A, etc.). Additionally, the base region 110 includes two vacuum ports 172 connected to the rotary stage 165 (illustrated in FIG. 1). The two vacuum ports 172 are a multi-stage seal with the rotary stage 165 to allow for rotation of the rotary stage 165 while maintaining a vacuum at the rotary stage 165.

The optical fiber coupler 180 is coupled to the base region 110 via screws, bolts, clamps, or another means. The optical fiber 182 is mounted into the optical fiber coupler 180, and the thermal radiation source 185 provides thermal radiation through the optical fiber 182 and into the base region 110 and reactor region 105 along the central axis A. During CVD synthesis, the thermal radiation passes through the central bore 144 and heats a sample mounted onto the top surface 142 of the sample mount 140. The chemical precursors in the deposition volume 125 then react and form atomic and molecular layers on the sample. As the sample is heated and deposition occurs, black body radiation is released from the sample in a generally isotropic manner. At least a portion of the blackbody radiation propagates along the central axis A toward the imaging region 107. Additionally, excess thermal radiation that is not absorbed by the sample propagates along the central axis A along with the black body radiation. The dichroic mirror 101 transmits the excess thermal radiation and any black body radiation having wavelengths in the same band as the thermal radiation. The dichroic mirror 101 reflects the rest of the black body radiation and the shortpass filter 102 further filters out any additional excess thermal radiation. The optical pyrometer 103 detects the black body radiation emitted from the sample during CVD synthesis. The optical pyrometer 103 provides a thermal map or image of the sample based on the detected black body radiation. A feedback loop may be provided between the pyrometer 103 and a processor or the thermal radiation source 185 to control the temperature of a sample and to maintain a steady state temperature of the sample.

Providing the thermal radiation along the central axis A allows for the thermal radiation to heat the sample through the central bore 144 without the thermal radiation contacting and heating up any other parts of the system 100. Therefore, the thermal load is isolated to the sample which reduces the thermal stress and strain on nearby components such as the inner sleeve 123, the outer chamber wall 115, optical components, etc. Using a 1 KW IR laser as the thermal radiation source 185, the temperature of the sample during CVD growth can reach 2000° C. or higher, with usual operation between 1500° C. and 1700° C. By reducing the amount of heat on other parts of the system 100 the thermal heat sinking is also simplified allowing for the use of a few fluid coolant lines instead of more complex and costly cooling systems.

The system 100 was constructed and X-ray imaging of a sample was performed during CVD synthesis. To characterize the sample, pyrometer heat mapping, X-ray diffraction analysis, and crystal truncation rod measurements were performed. The system 100 used a high-power, 1070 nm, 1 KW, near-IR laser source as the thermal radiation source 185. The thermal radiation was collimated via the optical fiber coupler 180 and the thermal radiation was provided to a sample mounted on the top surface 142 of the sample mount 140. A synchrotron was used as the X-ray source 195 which provided hard X-rays of greater than 20 keV for probing the sample during CVD synthesis. The outer chamber wall 115 was fused quartz, and the inner sleeve 123 was graphite, both of which are transparent to X-rays at greater than 20% and greater than 90% respectively. In examples, each of the outer chamber wall 115 and the inner sleeve 123 may individually be transmissive to X-ray radiation at between 10% and 30%, between 30% and 50%, between 50% and 70%, between 70% and 90%, or greater than 90%. A person of ordinary skill in the art would recognize that the transmission of the X-ray radiation depends not only on the material to propagate through, but also on the wavelength or energy of the X-ray radiation, and the thickness of the material to propagate through. For example, at 20 keV the 1 mm of graphite is about 92.28% transmissive, while 3 mm of fused quartz is 21.5% transmissive to the X-ray radiation. While at 25 keV, X-ray transmission through 1 mm of graphite is about 94.47%, while transmission through 3 mm of fused quartz is about 44%. As such, together, the outer chamber wall 115 and inner sleeve 123 act as an X-ray window for X-rays to pass through for performing in-situ measurements of material processes occurring in the deposition volume 125. The dichroic mirror 101 had a longpass wavelength of 650 nm, and the lowpass filter had a cutoff wavelength of 1000 nm.

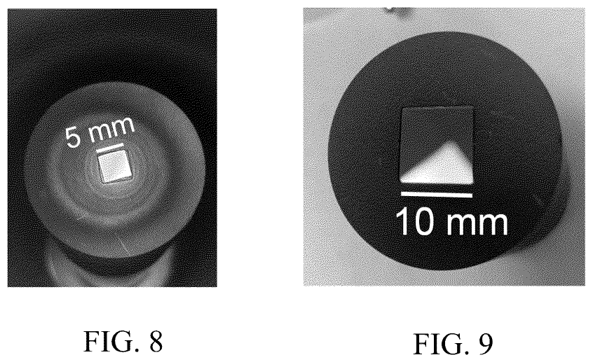

FIG. 8 is an image of a 5 mm square sample disposed on the top surface 142 of the sample mount 140. The sample mount 140 can be removed and replaced with sample mounts of different sizes to support different sized samples for performing CVD synthesis. FIG. 9 is an image of a 10 mm square sample disposed on the top surface 142 of the sample mount 140. The sample of FIGS. 8 and 9 was a SiC substrate.

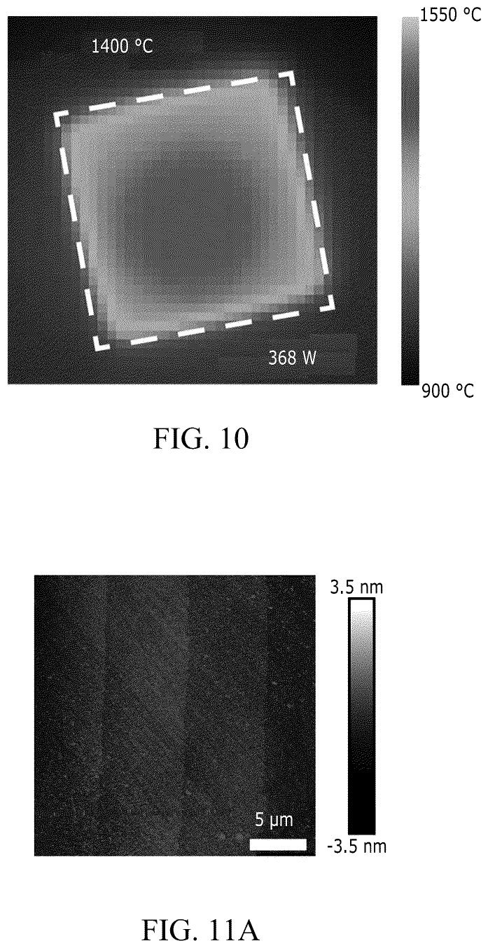

FIG. 10 is a heat map generated by the optical pyrometer 106 during CVD synthesis on a sample. The IR laser radiation from the thermal radiation source 185 heats the sample to around 1400° C. near the center of the sample, with a heat gradient that reduces toward the edges of the sample. About 50% of the sample is at a temperature of between 1350° C. and 1400° C. The sample imaged is a 5 mm square sample, such as the sample shown in FIG. 8. If a more even heat distribution is desired, the optical fiber collimator 180 may be replaced with a collimator providing a different beam profile. For example, a more drastic thermal gradient may be desired to form more CVD deposition near the center of the sample with less CVD deposition occurring near the edges of the sample. Under X-ray probing and analysis, different thermal radiation profiles of the sample may be useful in determining different thermal, pressure, and chemical precursor conditions for fabricating a desired atomic or molecular structure.

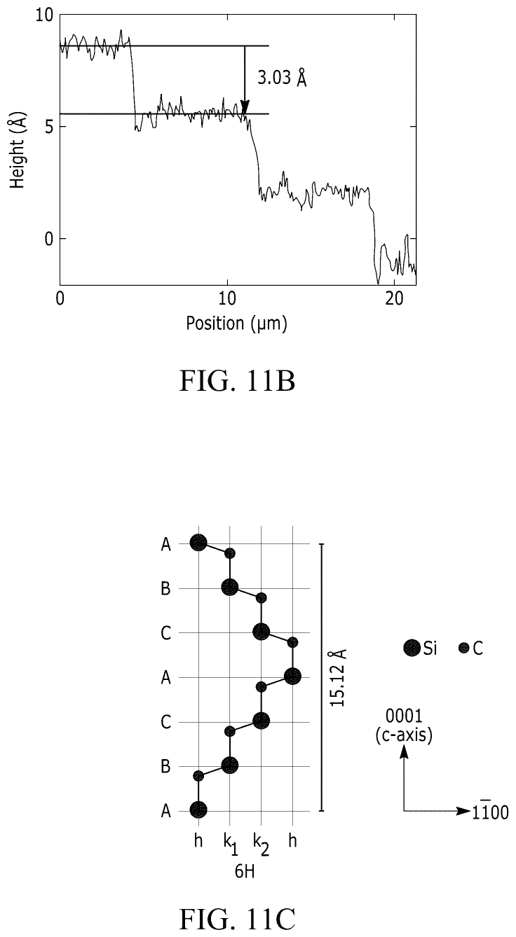

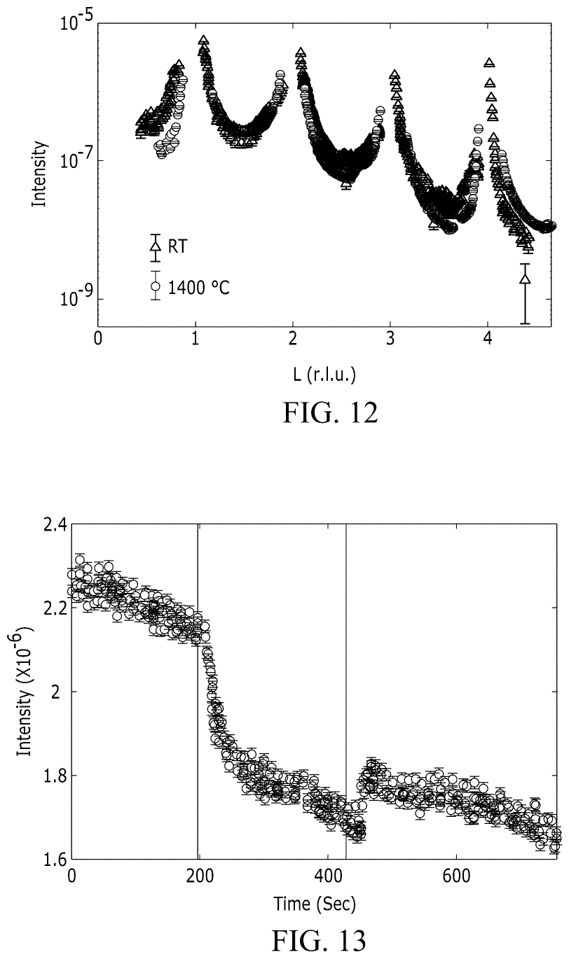

FIG. 11 is an atomic force microscope (AFM) image of a SiC substrate before growth showing approximately 3 angstrom high terraces, FIG. 11B is a plot of substrate height in angstroms of a line cut of the 6H-SiC substrate of FIG. 11A., and FIG. 11C is an associated diagram of an atomic crystal structure diagram of the 6H-SiC substrate of FIG. 11A. The substrate of FIG. 11 was subjected to typical CVD pre-growth conditions used to prepare the surface for synthesis: a temperature of 1400° C. while flowing 5% H₂/Ar into the deposition volume 125. FIG. 12 is an X-ray CTR measurement plot of the substrate of FIG. 11 before CVD deposition, and the substrate after about an hour under 1400° C. with a flow of 5% H₂/Ar. The data in the plot shows that there is a change in the intensities of the surface-sensitive low-intensity midzones (the regions between the Bragg peaks) which signifies changes to the molecular structure of the surface of the substrate due to etching. The x-axis reports the reciprocal lattice unit L (r.l.u.=reciprocal lattice unit) where L is the index of the scattering vector. The scattering vector is, in general, described by the Miller indices HKL. For a hexagonal crystal system, such as for SiC, the Miller-Bravais indices are used, HKIL. For the experimental CTR data presented in FIG. 12 H=1, K=0, I=−1, and the data are measured as a function of L, which is controlled by changing the measured exit angle of the X-ray beam reflected off the sample surface via moving the X-ray detector 197. The Y-axis presents the intensity of the reflected X-ray radiation as measured by an X-ray detector.

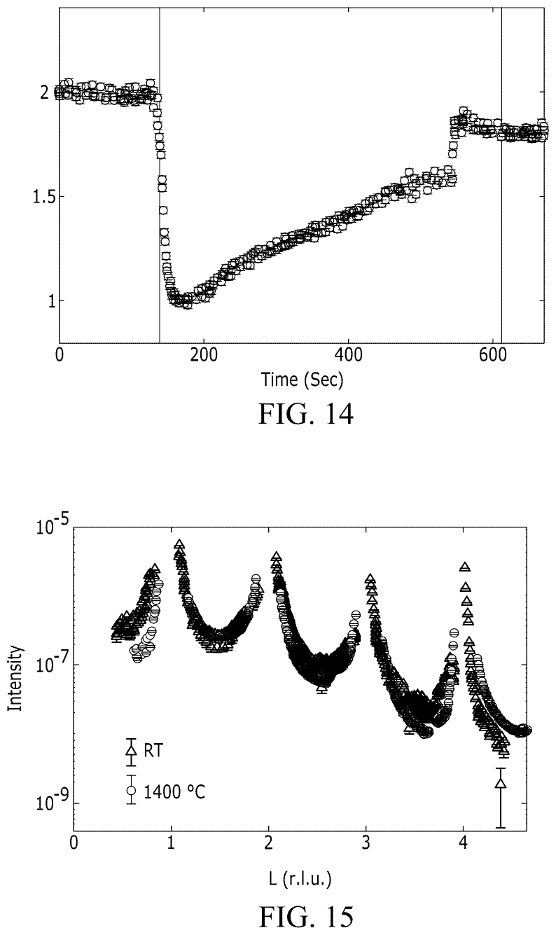

After the pregrowth etching process was performed under 1400° C. with a flow of 5% H₂/Ar, the temperature was increased to 1450° C., and chemical precursors were introduced for CVD synthesis. 15 standard cubic centimeters per minute (sccm) of dilute CH₄ and Si₂H₆ were flowed into independent mixing areas upstream of the deposition volume 125 with a concentration of 0.4% and 0.2% balanced in H₂, respectively. Both the CH₄ and the Si₂H₆ were further diluted by mixing each with 100 sccm of pure H₂, and these diluted concentrations were flowed into the chamber at 10 sccm each along with a 3% H₂/Ar carrier gas. Therefore, the resultant concentrations in the deposition chamber 121 were 2.48e-4% Si₂H₆+4.97e-4% CH₄+4.76% H₂/Ar. The C/Si ratio, a common metric reported for SiC CVD synthesis, during the growth was 1. FIG. 13 is a plot of a time-resolved measurement of changes in X-ray scattering intensity at a specific surface-sensitive momentum transfer along the CTR (HKIL=1 0-1 0.6) during alternating gas flow conditions of etching with 5% H₂/Ar and growth with reactive SiC precursor flow conditions of 2.48e-4% Si₂H₆+4.97e-4% CH₄+4.76% H₂/Ar. FIG. 14 is another plot of time-resolved measurement of changes in X-ray scattering intensity at a specific surface-sensitive momentum transfer along the CTR (HKIL=1 0−1 0.6) during alternating gas flow conditions of etching with 5% H₂/Ar and growth with reactive SiC precursor flow conditions of 0.0019% Si₂H₆+0.0038% CH₄+˜5% H₂/Ar, a higher concentration than was flowed during the measurement shown in FIG. 13. A reduced scattering intensity does not indicate loss of material. The reduced scattering intensity indicates a change in the structure of a surface. Thus, the results of FIGS. 13 and 14 demonstrate the ability to measure growth on a surface in-situ during material deposition. When the precursor flow was stopped (i.e., return to a flow of 5% H₂/Ar gas), which chemically etches the surface, the intensity begins to increase again. Thus, the surface structure begins to return back toward what it was before the introduction of the precursors at time=200s in FIG. 13 and at 120s in FIG. 14. The curved slopes at times when precursor flows were introduced, and stopped, indicate time constants of the respective processes (i.e., transitioning from a steady-state etching process to a steady-state growth process and vice versa). From the data presented in FIGS. 13 and 14, the measured time constants of the etching and growth processes appear to be different, indicating that the kinetics of etching away the new material is different from the kinetics of growing a new material on a prepared surface. Comparing the data of FIGS. 13 and 14, different trends can be identified in the reflected X-ray intensity as growth is started, and stopped. In particular, with a higher concentration of precursors, a larger change in the reflected intensity is observed when the precursor flow is begun as compared to the effect with lower precursor concentrations. Thus a larger difference in the climate and environment in the deposition volume 125 results in a greater change in the surface structure by using a higher concentration of precursors. Additionally, with a higher concentration of precursor flow, the reflected intensity has an initial drop followed by an upward trend, whereas there is an overall decrease in reflected intensity in the case of the lower precursor concentration. In general, the structure of new growth depends on precursor concentration, and, as demonstrated by the data of FIGS. 13 and 14, the described system is capable of measuring and characterizing these new growth structures.

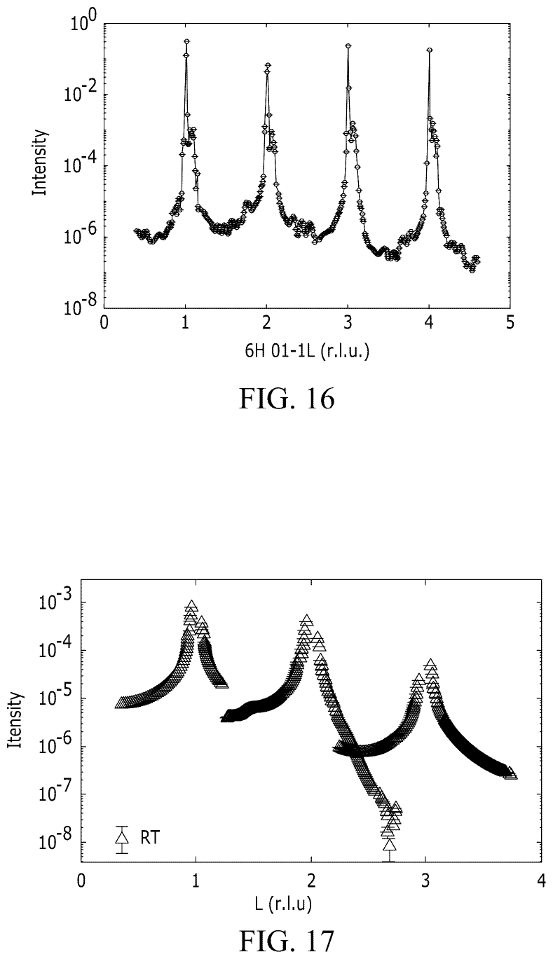

FIG. 15 is the plot of FIG. 12, presented again for convenience, of an X-ray CTR measurement showing Bragg peaks of a 6H-SiC substrate before CVD deposition, and after about an hour of the pre-growth etching process under 1400° C. with a flow of 5% H₂/Ar. FIG. 16 is a plot of the post-CVD synthesis X-ray CTR measurement of the same sample of FIG. 15. The fringes between the Bragg peaks show that the surface quality of the resultant CVD deposition film is good. A rougher surface would result in the decreased fringe contrast limiting the fringe visibility. Therefore, the ability to resolve the fringes with high contrast indicates a surface with a low level of surface roughness. The peaks also show that the deposition is partially epitaxial resulting in partial layers deposited over other layers, and that there is no 4H SiC present in the epitaxial structure.

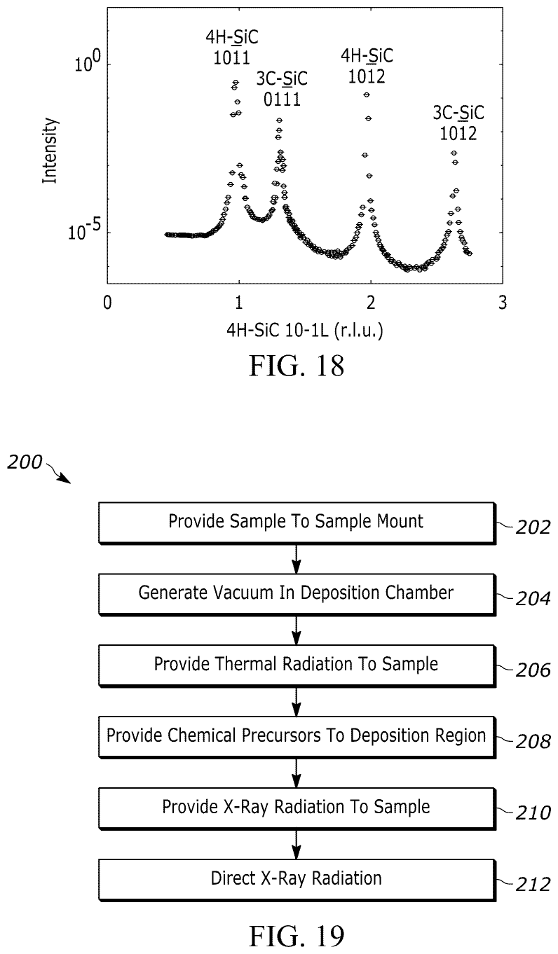

FIG. 17 is a plot of an X-ray CTR measurement showing Bragg peaks of a 4H-SiC substrate before CVD or other sample processing. Three Bragg peaks are present indicating that the substrate contains a 4H SiC polytype. FIG. 18 is a plot of X-ray CTR data, of a CVD fabricated thin film on the sample of FIG. 17 after various CVD growth cycles. The CVD growth cycles were performed at a temperature of 1500° C. using the system described herein. The data presented in FIG. 18 shows two additional peaks as compared to the CTR shown in FIG. 17. The two new peaks are at 1.33 r.l.u. and 2.66 r.l.u which are indicative of the presence of the 3C-SiC polytype. The ability to observe the formation of the 3C-SiC polytype during CVD synthesis allows for the tuning of system parameters in real time to adjust the formation or concentration of the 3C-SiC polytype, reduce the formation of the 3C-SiC polytype, or to adjust the CVD parameters to further form CVD deposition of other polytypes in a same substrate.

FIG. 19 is a flow diagram of a method 200 of performing in-situ X-ray analysis of a sample during CVD synthesis using the system described herein. For clarity, the method 200 will be described with reference to elements of the system 100 of FIGS. 1-3. The method 200 includes providing a sample to a sample mount, such as the top surface 142 of the sample mount 140 (block 202). The sample may include an SiC substrate, or another substrate for performing CVD deposition thereon. The sample mount 140 is disposed inside of the deposition region 125 of the deposition chamber 121 for performing CVD deposition. A vacuum is then generated in the deposition chamber 121, and the base region 110, via the vacuum ports 172 (block 204).

The thermal radiation source 185 then provides the thermal radiation along the deposition axis A to the sample (block 206). The sample is heated (e.g., to temperatures above 1400° C. for SiC deposition) and CVD is performed. The first, second, and third gas inlets 128a then provide chemical precursors to the deposition region 125 of the deposition chamber 121 (block 208). In examples, only one gas inlet may provide a chemical precursor, two gas inlets may individually provide chemical precursors, or all three gas inlets may provide chemical precursors depending on a desired molecular structure and material to be synthesized during CVD.

While the sample is heated and the chemical precursors are being provided to the deposition chamber, the X-ray radiation source 195 provides the X-ray radiation 198 to the sample (block 210). The X-ray radiation 198 propagates through the outer chamber wall 125 and the inner sleeve 123 into the deposition chamber 121. The X-ray radiation 198 is incident on the sample and the scattered X-ray radiation 198 propagates out of the deposition chamber 121 through the inner sleeve 123 and outer chamber wall 125. The X-ray detector 197 then detects the X-ray radiation 198 (block 212) outside of the deposition chamber 121. The detected X-ray radiation can then be analyzed for determining X-ray imaging, X-ray spectroscopy, and/or X-ray CTR measurements.

The following list of aspects reflects a variety of the embodiments explicitly contemplated by the present disclosure. Those of ordinary skill in the art will readily appreciate that the aspects below are neither limiting of the embodiments disclosed herein, nor exhaustive of all of the embodiments conceivable from the disclosure above, but are instead meant to be exemplary in nature.

1. A system for performing material deposition, the system including: a deposition chamber having (i) an outer chamber wall surrounding a chamber volume, (ii) an inner sleeve disposed inside of the chamber volume with a buffer region between the outer chamber wall and the inner sleeve, the inner sleeve surrounding a deposition volume for performing deposition of materials, (iii) a sample mount disposed in the deposition volume and configured to receive a sample to support a position and orientation of the sample in the deposition volume, and (iv) one or more vacuum ports for generating a vacuum environment inside of the deposition chamber; one or more gas inlets in fluid communication with the deposition chamber to allow fluid to flow into the deposition chamber; one or more gas outlets in fluid communication with the deposition chamber to allow fluid to flow out of the deposition chamber; one or more heatsink elements thermally coupled to the deposition chamber configured to extract heat from the deposition chamber; and a thermal radiation source configured to provide thermal radiation to the deposition volume along a deposition axis, the deposition axis being perpendicular to a normal vector of the outer chamber wall and the sample mount being disposed along the deposition axis.

2. The system of aspect 1, wherein the inner sleeve comprises graphite.

3. The system of either of aspect 1 or aspect 2, wherein the outer chamber wall comprises fused quartz.

4. The system of any of aspects 1 to 3, wherein the radiation source comprises a laser optically coupled to the deposition chamber to provide radiation to the deposition volume.

5. The system of aspect 4, wherein the laser comprises an infrared laser.

6. The system of any of aspects 1 to 5, wherein the one or more gas fluid inlets comprises: a first gas fluid inlet in fluid communication with a first precursor zone; a second gas fluid inlet in fluid communication with a second precursor zone, and a third gas fluid inlet in fluid communication with a third precursor zone.

7. The system of any of aspects 1 to 6, further comprising: an x-ray radiation source configured to provide x-ray radiation to the deposition volume through the outer chamber wall and the inner sleeve; and an x-ray detector disposed outside of the deposition chamber, the x-ray detector configured to receive x-ray radiation from the deposition chamber.

8. The system of any of aspects 1 to 7, further comprising a thermal detector disposed outside of the deposition chamber configured to receive thermal radiation from the deposition volume.

9. The system of aspect 8, wherein the thermal detector comprises an optical pyrometer.

10. The system of any of aspects 1 to 9, wherein the one or more heatsink elements comprises one or more water cooling lines thermally coupled to the deposition chamber.

11. The system of any of aspects 1 to 10, further comprising a rotary mount physically coupled to the sample mount and configured to rotate the sample mount about an axis parallel to the deposition axis.

12. A method of actively imaging a sample during fabrication of the sample, the method including: providing a sample to a sample mount disposed in a deposition chamber, the deposition chamber having: an outer chamber wall surrounding a chamber volume, and an inner sleeve disposed inside of the chamber volume with a buffer region between the outer chamber wall and the inner sleeve, the inner sleeve surrounding a deposition volume; generating a vacuum inside of the deposition chamber; providing, via one or more fluid inlet ports, reactive precursor agents to the deposition volume; providing, via a thermal radiation source, thermal radiation to the sample, the thermal radiation provided along a deposition axis, and wherein the sample mount is disposed along the deposition axis; providing, via an X-ray radiation source, X-ray radiation to the sample; and detecting, via an X-ray detector, the X-ray radiation.

13. The method of claim 12, wherein the inner sleeve comprises graphite.

14. The method of either of aspect 12 or aspect 13, wherein the outer chamber wall comprises fused quartz.

15. The method of any of aspects 12 to 14, wherein the thermal radiation source comprises a laser optically coupled to the deposition chamber to provide radiation to the deposition volume.

16. The method of aspect 15, wherein the laser comprises an infrared laser.

17. The method of any of aspects 12 to 16, wherein the one or more gas fluid inlets comprises: a first gas fluid inlet in fluid communication with a first precursor zone; a second gas fluid inlet in fluid communication with a second precursor zone, and a third gas fluid inlet in fluid communication with a third precursor zone.

18. The method of any of aspects 12 to 17, further comprising: an x-ray radiation source configured to provide x-ray radiation to the deposition volume through the outer chamber wall and through the inner sleeve; and an x-ray detector disposed outside of the deposition chamber, the x-ray detector configured to receive x-ray radiation from the deposition chamber.

19. The method of any of aspects 12 to 18, further comprising a thermal detector disposed outside of the deposition chamber configured to receive thermal radiation from the deposition volume.

20. The method of any of aspects 12 to 19, wherein the sample stage is physically coupled to a rotary mount such that the rotary mount can rotate the sample stage about an axis parallel to the deposition axis.

What is claimed is:

1. A system for performing material deposition, the system comprising:
a deposition chamber having (i) an outer chamber wall surrounding a chamber volume, (ii) an inner sleeve disposed inside of the chamber volume with a buffer region between the outer chamber wall and the inner sleeve, the inner sleeve surrounding a deposition volume for performing deposition of materials, (iii) a sample mount disposed in the deposition volume and configured to receive a sample to support a position and orientation of the sample in the deposition volume, and (iv) one or more vacuum ports for generating a vacuum environment inside of the deposition chamber;
one or more gas inlets in fluid communication with the deposition chamber to allow fluid to flow into the deposition chamber;
one or more gas outlets in fluid communication with the deposition chamber to allow fluid to flow out of the deposition chamber; and
a thermal radiation source configured to provide thermal radiation to the deposition volume along a deposition axis, the deposition axis being perpendicular to a normal vector of the outer chamber wall and the sample mount being disposed along the deposition axis.

2. The system of claim 1, wherein the inner sleeve comprises graphite.

3. The system of claim 1, wherein the outer chamber wall comprises fused quartz.

4. The system of claim 1, wherein the radiation source comprises a laser optically coupled to the deposition chamber to provide radiation to the deposition volume.

5. The system of claim 4, wherein the laser comprises an infrared laser.

6. The system of claim 1, wherein the one or more gas fluid inlets comprises:
a first gas fluid inlet in fluid communication with a first precursor zone;
a second gas fluid inlet in fluid communication with a second precursor zone, and
a third gas fluid inlet in fluid communication with a third precursor zone.

7. The system of claim 1, further comprising:
an x-ray radiation source configured to provide x-ray radiation to the deposition volume through the outer chamber wall and the inner sleeve; and
an x-ray detector disposed outside of the deposition chamber, the x-ray detector configured to receive x-ray radiation from the deposition chamber.

8. The system of claim 1, further comprising a thermal detector disposed outside of the deposition chamber configured to receive thermal radiation from the deposition volume.

9. The system of claim 8, wherein the thermal detector comprises an optical pyrometer.

10. The system of claim 1, further comprising one or more heatsink elements thermally coupled to the deposition chamber configured to extract heat from the deposition chamber.

11. The system of claim 10, wherein the one or more heatsink elements comprises one or more water cooling lines thermally coupled to the deposition chamber.

12. The system of claim 1, further comprising a rotary mount physically coupled to the sample mount and configured to rotate the sample mount about an axis parallel to the deposition axis.

13. A method of actively imaging a sample during fabrication of the sample, the method comprising:
providing a sample to a sample mount disposed in a deposition chamber, the deposition chamber having:
an outer chamber wall surrounding a chamber volume, and
an inner sleeve disposed inside of the chamber volume with a buffer region between the outer chamber wall and the inner sleeve, the inner sleeve surrounding a deposition volume with the sample mount disposed inside of the deposition volume, the sample mount configured to support a position and orientation of the sample in the deposition volume;
one or more vacuum ports for generating a vacuum environment inside of the deposition chamber;
generating, via the one or more vacuum ports, a vacuum inside of the deposition chamber;
providing, via a thermal radiation source, thermal radiation to the sample, the thermal radiation provided along a deposition axis, and wherein the sample mount is disposed along the deposition axis;
providing, via one or more gas inlet ports in fluid communication with the deposition chamber, reactive precursor agents to the deposition volume;
exhausting, via one or more gas outlets in fluid communication with the deposition chamber, fluid flow out of the deposition chamber;
providing, via an X-ray radiation source, X-ray radiation to the sample; and
detecting, via an X-ray detector, the X-ray radiation.

14. The method of claim 13, wherein the inner sleeve comprises graphite.

15. The method of claim 13, wherein the outer chamber wall comprises fused quartz.

16. The method of claim 13, wherein providing thermal radiation comprises providing thermal radiation via a laser optically coupled to the deposition chamber.

17. The method of claim 16, wherein providing thermal radiation via a laser comprises providing thermal radiation via an infrared laser.

18. The method of claim 13, wherein providing reactive precursor agents to the deposition volume comprises:
providing a first precursor via a first gas fluid inlet in fluid communication with a first precursor zone;
providing a second precursor via a second gas fluid inlet in fluid communication with a second precursor zone, and
providing a third precursor via a third gas fluid inlet in fluid communication with a third precursor zone.

19. The method of claim 13, wherein providing X-ray radiation to the sample comprises providing X-ray radiation to the deposition volume through the outer chamber wall and through the inner sleeve.

20. The method of claim 13, wherein the sample stage is physically coupled to a rotary mount such that the rotary mount can rotate the sample stage about an axis parallel to the deposition axis.
